(19) United States
(12) Patent Application Publication
(10) Pub. No.: US 2023/0141625 A1
(43) Pub. Date: May 11, 2023

(54) CONDUCTIVE PASTE FOR SOLAR CELL ELECTRODE AND SOLAR CELL MANUFACTURED BY USING SAME

(71) Applicant: LS-NIKKO COPPER INC., Ulsan (KR)

(72) Inventors: In Chul KIM, Yongin-si (KR); Chung Ho KIM, Namyangju-si (KR); Kang Ju PARK, Seongnam-si (KR); Min Soo KO, Seoul (KR); Mun Seok JANG, Seoul (KR); Tae Hyun JUN, Seongnam-si (KR); Hwa Joong KIM, Guri-si (KR)

(21) Appl. No.: 17/914,555

(22) PCT Filed: Dec. 29, 2020
(86) PCT No.: PCT/KR2020/019266

§ 371 Date: Sep. 26, 2022

(30) Foreign Application Priority Data
Mar. 25, 2020 (KR) 10-2020-0036247

(51) Int. Cl. H01L 31/0224

(52) U.S. Cl. CPC H01L 31/022425

(57) ABSTRACT

The present disclosure provides a conductive paste for a solar cell electrode, comprising a metal powder, a glass frit, a metal oxide, an organic binder and a solvent, wherein the metal oxide comprises at least one metal oxide selected from the group consisting of tungsten (W), antimony (Sb), nickel (Ni), copper (Cu), magnesium (Mg), calcium (Ca), ruthenium (Ru), molybdenum (Mo), and bismuth (Bi).

### TECHNICAL FIELD

The present disclosure relates to a conductive paste for a solar cell electrode and a solar cell including the same. More particularly, the present disclosure relates to a conductive paste for a solar cell electrode having an improved composition and a solar cell including the same.

### BACKGROUND ART

As existing energy resources such as oil and coal are expected to be depleted soon, interest in alternative energy to replace them is increasing. Among them, a solar cell is spotlighted as a next-generation energy source that converts solar energy into electrical energy.

A solar cell is a semiconductor device that converts solar energy into electrical energy and generally has a p-n junction form, and the basic structure of a solar cell is the same as that of a diode. FIG. 1 shows the structure of a general solar cell device, the solar cell device is generally constructed using a p-type silicon semiconductor substrate 10 having a thickness in a range of 180 to 250 μm. An n-type impurity layer 20 having a thickness in a range of 0.3 to 0.6 μm is formed on the light-receiving surface side of the silicon semiconductor substrate, and an anti-reflection film 30 and a front electrode 100 are formed thereon. In addition, a rear electrode 50 is formed on the rear surface side of the p-type silicon semiconductor substrate. The front electrode 100 is formed by coating a conductive paste mixed with metal powder containing silver as the main component, glass frit, an organic vehicle, and an additive on the anti-reflection film 30 and then sintering the coated conductive paste. The rear electrode 50 is formed by coating an aluminum paste composition composed of aluminum powder, glass frit, an organic vehicle, and an additive by screen printing, etc., drying, and then sintering at a temperature of 660° C. (melting point of aluminum) or higher. At this time, aluminum is diffused into the p-type silicon semiconductor substrate during the sintering, thereby forming an Al—Si alloy layer between the rear electrode and the p-type silicon semiconductor substrate and simultaneously forming a p⁺ layer 40 as an impurity layer due to the diffusion of aluminum atoms. The presence of such a p⁺ layer prevents the recombination of electrons and provides a back surface field (BSF) effect that improves the collection efficiency of generated carriers. A rear silver electrode 60 may be further positioned under the rear aluminum electrode 50.

In addition to the short-circuit current (Isc), open-circuit voltage (Voc), and incident light amount (W), the fill factor (FF) is an important determinant of solar cell efficiency (%). The fill factor (FF) is the value obtained by dividing the maximum output by the product of the open-circuit voltage and the short-circuit current. The internal series resistance (Rs) of the solar cell is one of the factors affecting the fill factor (FF), and as the series resistance increases, the fill factor (FF) decreases, thereby reducing the solar cell efficiency. One of the main causes of the series resistance is that there is an ohmic contact between the emitter layer and the electrode. The ohmic contact is a resistance generated by a gap that occurs when metal and semiconductors are in electrical contact, and when this value is large, there is a problem in that the fill factor (FF) is lowered due to a large contact resistance value generated between the metal electrode and the emitter layer when manufacturing the solar cell electrode, thereby reducing the solar cell efficiency.

In addition, recently, the thickness of the emitter has been continuously made thin in order to increase the efficiency of the solar cell. As a result, a shunting phenomenon that may degrade the performance of a solar cell occurs, and at the same time, there is a problem in that the contact resistance increases due to an increase in the area of the solar cell, thereby reducing the efficiency of the solar cell.

In order to improve this problem, conventional research has been conducted to improve contact resistance by increasing the amount of glass frit, which is an inorganic additive, in the paste composition. However, when the amount of glass frit is increased, there is a limit in that the open-circuit voltage (Voc) is reduced, and the leakage current is increased.

### DISCLOSURE

### Technical Problem

An objective of the present disclosure is to provide a conductive paste composition for a solar cell electrode and a solar cell including the same. The conductive paste composition of the present disclosure includes a specific metal oxide with glass frit in a specific content in order to solve the above problems and improve the efficiency and characteristics of the solar cell, thereby increasing the open circuit voltage (Voc), the leakage current, and the contact resistance.

However, the objectives of the present disclosure are not limited to the above-mentioned objectives, and other objectives not mentioned will be clearly understood by those skilled in the art from the following description.

### Technical Solution

The present disclosure provides a conductive paste for a solar cell electrode, the conductive paste includes metal powder, glass frit, a metal oxide, an organic binder, and solvent, in which the metal oxide includes at least one metal oxide selected from the group consisting of tungsten (W), antimony (Sb), nickel (Ni), copper (Cu), magnesium (Mg), calcium (Ca), ruthenium (Ru), molybdenum (Mo), and bismuth (Bi).

In this case, the content of the metal oxide is 0.01% to 0.5% by weight based on the total weight of the conductive paste.

In addition, the average particle size of the metal oxide is in a range of 0.01 to 0.5 μm.

In addition, the metal oxide includes tungsten oxide (WO₃).

Furthermore, the content of the glass frit is 0.5% to 5.0% by weight based on the total weight of the conductive paste.

In addition, the present disclosure provides a solar cell having a front electrode on an upper portion of a substrate and a rear electrode on a lower portion of the substrate, in which the front electrode is manufactured by coating the conductive paste for the solar cell electrode and drying and sintering the coated conductive paste.

### Advantageous Effects

The present disclosure provides a conductive paste for a solar cell electrode containing a metal oxide together with a metal powder, a glass frit, an organic binder, and a solvent.

More specifically, the conductive paste for a solar cell electrode of the present disclosure contains a specific content of one or more metal oxides selected from the group consisting of tungsten oxide (WO₃), nickel oxide (NiO), copper oxide (CuO), and bismuth oxide (Bi₂O₃). Even when a high content of glass frit is included, it is possible to prevent an increase in the leakage current value and a decrease in the open-circuit voltage (Voc) and to improve the fill factor by reducing the series resistance (Rs), thereby increasing the solar cell conversion efficiency.

### DESCRIPTION OF DRAWINGS

FIG. 1 is a cross-sectional view schematically showing an example of a solar cell to which the conductive paste for a solar cell electrode according to the present disclosure is applied.

### EXPLANATION OF SYMBOLS

10: P-type silicon semiconductor substrate
20: N-type impurity layer
30: Anti-reflection film
40: P⁺ layer (BSF: back surface field)
50: Rear aluminum electrode
60: Rear silver electrode
100: Front electrode

### BEST MODE

Before describing the present disclosure in detail below, it should be understood that the terms used in the present specification are for describing a specific embodiment and are not intended to limit the scope of the present disclosure limited only by the scope of the appended patent claim. All technical and scientific terms used herein have the same meaning as commonly understood by those of ordinary skilled in the art unless otherwise stated.

Throughout the specification and claims, unless otherwise stated, the term “comprise”, “comprises”, and “comprising” means including the mentioned objective, step, or group of objects and is not used to exclude any other objective, step, or group of objects or groups of objectives.

On the other hand, various embodiments of the present disclosure may be combined with any other embodiments unless clearly indicated to the contrary. Any feature indicated as particularly preferred or advantageous may be combined with any other feature and features indicated as preferred or advantageous. Hereinafter, embodiments of the present disclosure and effects thereof will be described with reference to the accompanying drawings.

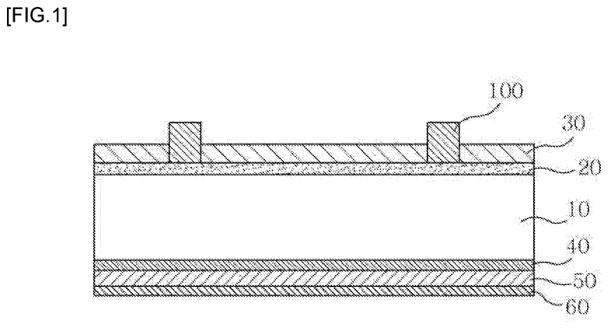

First, an example of a solar cell to which the conductive paste for a solar cell electrode according to the present disclosure is applied will be described with reference to FIG. 1, and then the conductive paste for a solar cell electrode according to the present disclosure and glass frit included therein will be described in detail.

FIG. 1 is a cross-sectional view schematically showing an example of a solar cell to which the conductive paste for a solar cell electrode, according to the present disclosure, is applied.

FIG. 1 shows the structure of a general solar cell device, and the solar cell device is generally constructed using a p-type silicon semiconductor substrate 10 having a thickness in a range of 180 to 250 μm. An n-type impurity layer 20 having a thickness in a range of 0.3 to 0.6 μm is formed on the light-receiving surface side of the silicon semiconductor substrate, and an anti-reflection film 30 and a front electrode 100 are formed thereon. In addition, a rear electrode 50 is formed on the rear surface side of the p⁻type silicon semiconductor substrate. The front electrode 100 is formed by coating a conductive paste mixed with metal powder containing silver as the main component, glass frit, an organic vehicle, and an additive on the anti-reflection film 30 and then sintering the coated conductive paste. The rear electrode 50 is formed by coating an aluminum paste composition composed of aluminum powder, glass frit, an organic vehicle, and an additive by screen printing, etc., drying, and then sintering at a temperature of 660° C. (melting point of aluminum) or higher. At this time, aluminum is diffused into the p-type silicon semiconductor substrate during the sintering, thereby forming an Al—Si alloy layer between the rear electrode and the p-type silicon semiconductor substrate and simultaneously forming a p⁺ layer 40 as an impurity layer due to the diffusion of aluminum atoms. The presence of such a p⁺ layer prevents the recombination of electrons and provides a back surface field (BSF) effect that improves the collection efficiency of generated carriers. A rear silver electrode 60 may be further positioned under the rear aluminum electrode 50.

In addition to the short-circuit current (Isc), open-circuit voltage (Voc), and incident light amount (W), the fill factor (FF) is an important determinant of solar cell efficiency (%). The fill factor (FF) is the value obtained by dividing the maximum output by the product of the open-circuit voltage and the short-circuit current. The internal series resistance (Rs) of the solar cell is one of the factors affecting the fill factor (FF), and as the series resistance increases, the fill factor (FF) decreases, thereby reducing the solar cell efficiency. One of the main causes of the series resistance is that there is an ohmic contact between the emitter layer and the electrode. The ohmic contact is a resistance generated by a gap that occurs when metal and semiconductors are in electrical contact, and when this value is large, there is a problem in that the fill factor (FF) is lowered due to a large contact resistance value generated between the metal electrode and the emitter layer when manufacturing the solar cell electrode, thereby reducing the solar cell efficiency.

In addition, recently, the thickness of the emitter is continuously made thin in order to increase the efficiency of the solar cell. As a result, a shunting phenomenon that may degrade the performance of a solar cell occurs, and at the same time, there is a problem in that the contact resistance increases due to an increase in the area of the solar cell, thereby reducing the efficiency of the solar cell.

In order to improve this problem, conventional research has been conducted to improve contact resistance by increasing the amount of glass frit, which is an inorganic additive, in the paste composition. However, when the amount of glass frit is increased, there is a limit in that the open-circuit voltage (Voc) is reduced, and the leakage current is increased.

Accordingly, the present disclosure provides a conductive paste for a solar cell electrode capable of improving the performance of a solar cell.

The conductive paste contains a specific metal oxide in a specific content along with the metal powder, glass frit, an organic binder, and solvent so that the leakage current value and the open circuit voltage (Voc) decrease even when the conductive paste contains a high content of the glass frit. It is possible to prevent an increase in the leakage current value and a decrease in the open-circuit voltage (Voc) and to improve the fill factor by reducing the series resistance (Rs), thereby increasing the solar cell conversion efficiency.

Hereinafter, the present disclosure will be described in more detail.

In one embodiment, the present disclosure provides a conductive paste for a solar cell electrode, including metal powder, glass frit, a metal oxide, an organic binder, and solvent.

In this case, silver (Ag) powder, gold (Au) powder, platinum (Pt) powder, nickel (Ni) powder, copper (Cu) powder, tin (Sn) powder, aluminum (Al) powder, molybdenum (Mo) powder, ruthenium (Ru) powder, etc., can be used as the metal powder. The above-described powder may be used alone, as an alloy using two or more types of metals, or as a mixed powder in which at least two of the above-described powders are mixed. In addition, a metal powder in which the surface of the metal powder is subjected to surface treatment, such as hydrophilic treatment, may be used.

Among them, it is preferable to use silver (Ag) powder which has excellent electrical conductivity and is mainly used for the front electrode 40. The silver powder is preferably a pure silver powder, and in addition, a silver-coated composite powder having at least a surface of a silver (Ag) layer, an alloy containing silver as the main component, or the like can be used. In some cases, the silver powder may be used by mixing with other metal powders, and the mixed metal powder may be, for example, aluminum (Al), gold (Au), palladium (Pd), copper (Cu), nickel (Ni), or the like.

In addition, the average particle size of the silver powder may be in a range of 0.05 to 3 μm, and it is preferable to be in a range of 0.5 to 2.5 μm considering the ease of paste formation and compactness during sintering, and the shape may be at least one of spherical shape, needle shape, plate shape, and amorphous shape. The silver powder may be used by mixing with two or more types of powders having different average particle diameters, particle size distributions, shapes, and the like.

The glass frit, according to the present disclosure, is the main material (a material having a molar ratio of 0.5 or more to the entire glass frit) and may include lead oxide (e.g., PbO), tellurium oxide (e.g., TeO₂), bismuth oxide (e.g., Bi₂O₃), and silicon oxide (e.g., SiO₂). In addition, the glass frit may further include at least one compound among boron oxide, zinc oxide, aluminum oxide, titanium oxide, calcium oxide, magnesium oxide, and zirconium oxide as additional material. As an example, a molar ratio of lead oxide may be 0.1 to 0.29, a molar ratio of tellurium oxide may be 0.2 to 0.38, a molar ratio of bismuth oxide may be 0.03 to 0.2, and a molar ratio of silicon oxide may be 0.2 or less each with respect to the total glass frit. In addition, the molar ratio of each of the additional materials with respect to the total glass frit may be 0.2 or less (e.g., 0.06 or less).

The average particle size of the glass frit is not limited but may have a particle size within a range of 0.05 to 4 μm, and various types of particles having different average particle sizes may be mixed and used. It is preferable to use at least one glass frit having an average particle size (D50) of 0.1 μm or more and 3 μm or less. Through this, the reactivity during sintering is enhanced, damage to the n-layer is minimized, particularly at a high temperature, adhesion is improved, and open-circuit voltage (Voc) can be improved. In addition, it is possible to reduce an increase in the line width of the electrode during sintering.

In addition, the glass transition temperature (Tg) of the glass frit is not limited but may be in a range of 200° C. to 500° C., and preferably, the glass transition temperature is in the range of 250° C. or more and less than 450° C. By using glass frit having a low glass transition temperature of less than 450° C., the melting uniformity may be increased, and the characteristics of the solar cell may be made uniform. In addition, excellent contact properties can be secured even during low-temperature/rapid sintering and may be optimized for high sheet-resistance (90 to 120 Ω/sq) solar cells.

In addition, the content of the glass frit may be 0.5% to 5.0% by weight based on the total weight of the conductive paste, and more preferably, 2.0% to 5.0% by weight or 2.8% to 5.0% by weight. When the content of the glass frit exceeds the upper limit, an increase in leakage current is induced, thereby degrading the efficiency of the solar cell, and when the content is less than the lower limit, the fill factor (FF) of the solar cell is insignificant.

The metal oxide used as an additive in the conductive paste includes at least one metal oxide selected from the group consisting of tungsten (W), antimony (Sb), nickel (Ni), copper (Cu), magnesium (Mg), calcium (Ca), ruthenium (Ru), molybdenum (Mo), and bismuth (Bi). As an example, the metal oxide may include an oxide of tungsten (W), and preferably, an oxide of tungsten (W) is necessarily included. Since the oxide of tungsten (W) has an effect of preventing a decrease in open-circuit voltage (Voc) and an increase in leakage current due to an increase in the content of the glass frit in the conductive paste, the contact resistance is improved, and series resistance (Rs) is reduced due to an increase in the content of the glass frit, thereby increasing the fill factor (FF), thereby increasing the efficiency of the solar cell.

In addition, the content of the metal oxide may be 0.01% to 0.5% by weight, preferably 0.05% to 0.35% by weight based on the total weight of the conductive paste. As an example, when the metal oxide is tungsten (W) oxide, the tungsten (W) oxide may be included in an amount of 0.05% to 0.35% by weight, preferably 0.05% to 0.25% by weight or 0.05% to 0.15% by weight based on the total weight of the conductive paste.

When the metal oxide is used exceeding the upper limit of the above-mentioned content, the contact characteristic is degraded and the fill factor (FF) is reduced, and when the metal oxide is used below the lower limit, the effect of preventing a decrease in the open voltage (Voc) and an increase in the leakage current due to an increase in the content of the glass frit is insignificant. As such, when the metal oxide (for example, WO₃) is included in a specific content, the metal oxide may effectively etch the aluminum oxide layer to improve contact characteristics, thereby preventing an increase in leakage current and a decrease in open voltage, thereby improving the fill factor (FF) of the solar cell.

In addition, the average particle size of the metal oxide may preferably be 0.01 to 0.5 μm, 0.05 to 0.3 μm, or 0.05 to 0.19 μm when considering the implemented effect. The metal oxide, according to the present disclosure, may have improved contact resistance and reduced series resistance (Rs) within the above-described average particle size range, thereby increasing the filling factor (FF).

In addition, the organic vehicle, including the organic binder and the solvent, has the property of maintaining a uniformly mixed state of the metal powder and the glass frit. For example, when a conductive paste is applied to a substrate by screen printing, an organic vehicle can homogenize the conductive paste to suppress blurring and smudge of the printing pattern and to allow the conductive paste from the screen plate to pass through and separate the plate easily.

Examples of such organic binders may include a cellulose ester-based compound, a cellulose ether-based compound, an acrylic compound, and a vinyl-based compound. Specifically, the cellulose ester-based compound may include cellulose acetate, cellulose acetate butyrate, and the like; the cellulose ether-based compound may include ethyl cellulose, methyl cellulose, hydroxy propyl cellulose, hydroxy ethyl cellulose, hydroxy propyl methyl cellulose, and hydroxy ethyl methyl cellulose; the acrylic compound may include polyacrylamide, polymethacrylate, polymethylmethacrylate, and polyethylmethacrylate; and the vinyl-based compound may include polyvinyl butyral, polyvinyl acetate, and polyvinyl alcohol. At least one organic binder may be selectively used.

In addition, the solvent is not particularly limited as long as it is generally used for the conductive paste. Specifically, the solvent may include at least one among alcohols such as ethanol, isopropanol, and terpineol; glycols such as ethylene glycol; esters such as dimethyl adipate, dimethyl glutarate, and dimethyl succinate; acetates such as ethyl acetate, butyl carbitol acetate, and ethyl carbitol acetate; ethers such as methyl cellosolve and butyl cellosolve; hydrocarbon-based organic solvents such as hexane, heptane, and paraffin oil; and aromatic hydrocarbon-based organic solvents such as benzene, toluene, and xylene. Preferably, dimethyl adipate, dimethyl glutarate, dimethyl succinate, and butyl carbitol acetate may be used.

The conductive paste composition according to the present disclosure may further include, if necessary, other commonly known additives, for example, a dispersing agent, a leveling agent, a plasticizer, a viscosity adjusting agent, a surfactant, an oxidizing agent, a metal-organic compound, a wax, and the like. Examples of the dispersing agent may include BYK-110, BYK-111, BYK-108, BYK-180, and the like, and the thickener may include BYK-410, BYK-411, BYK-420, and the like, and the thixotropic agent may include BYK-203, 204, 205, and the like, and the leveling agent may include BYK-308, BYK-378, BYK-3340, and the like, but is not limited thereto.

The content of the metal powder may be included in an amount of 70% to 95% by weight, preferably 85% to 95% by weight based on the total weight of the conductive paste when considering the thickness of the electrode formed during printing and the wire resistance of the electrode. When the content of the metal powder is less than 70% by weight (e.g., 85% by weight), the specific resistance of the formed electrode may be high, and when the content of the metal powder exceeds 95% by weight, the content of other components is not sufficient, so that the metal powder is not uniformly dispersed.

The content of the glass frit may be included in an amount of 0.1% to 15% by weight, preferably 0.5% to 5% by weight based on the total weight of the conductive paste. When the content of the glass frit is less than 0.1% by weight (for example, 0.5% by weight), there is a risk that the electrical specific resistivity may increase due to incomplete sintering, and when the content of the glass frit exceeds 15% by weight (for example, 5% by weight), the glass component in the sintered body of the silver powder becomes too large, and there is a risk that the electrical specific resistivity may also increase. The organic binder is not limited but may be included in an amount of 3% to 25% by weight based on 100% by weight of the total conductive paste. When the content of the organic binder is less than 3% by weight, the viscosity of the composition and adhesion of the formed electrode pattern may be reduced, and when the content of the organic binder exceeds 25% by weight, the amount of metal powder, solvent, dispersing agent, etc., may not be sufficient.

The solvent may be included in an amount of 5% to 25% by weight based on 100% by weight of the total conductive paste. When the content of the solvent is less than 5% by weight, the metal powder, glass frit, an organic binder, etc., may not be uniformly mixed, and when the content of the solvent exceeds 25% by weight, the amount of the metal powder decreases, thereby decreasing the electrical conductivity of the manufactured front electrode 40. The other additives are included in an amount of 0.1% to 5% by weight based on 100% by weight of the total conductive paste.

The above-described conductive paste for a solar cell electrode may be prepared by mixing and dispersing metal powder, glass frit, metal oxide, organic binder, solvent, and additives, and then filtering and defoaming.

In addition, in one embodiment of the present disclosure, the present disclosure provides a solar cell having a front electrode on an upper portion of a substrate and a rear electrode on a lower portion of the substrate, in which the front electrode is manufactured by coating the conductive paste for the solar cell electrode and drying and sintering the coated conductive paste.

Furthermore, the present disclosure provides a method for forming an electrode of a solar cell, in which the conductive paste is coated on a substrate, dried, and sintered, and a solar cell electrode is manufactured by the method. Except for using the conductive paste containing a specific metal oxide in a specific content as described above in the method for forming the solar cell electrode of the present disclosure, the substrate, printing, drying, and sintering methods may be generally used in manufacturing the solar cell.

As an example, the substrate may be a silicon wafer, the electrode made of the paste of the present disclosure may be a front finger bar electrode or a bus bar electrode, and the printing may be screen printing or offset printing, drying may be performed at 90° C. to 350° C., and the sintering may be performed at 600° C. to 950° C. Preferably, the sintering is performed at a high temperature/high-speed sintering at 800° C. to 950° C., more preferably at 850° C. to 900° C. for 5 seconds to 1 minute, and the printing is performed to have a thickness in a range of 20 to 60 μm.

In addition, the conductive paste, according to the present disclosure, may be applied to structures such as a crystalline solar cell (p-type, n-type), passivated emitter solar cell (PESC), passivated emitter and rear cell (PERC), passivated emitter rear locally diffused (PERL), etc., and the changed printing process such as double printing and dual printing.

According to the present disclosure, the fill factor (FF) can be improved by containing the glass frit at a specific weight in order to improve the contact resistance by reducing the series resistance. In addition, by adding a specific weight of tungsten (W) metal oxide, it is possible to prevent an open circuit voltage (Voc) decrease and a leakage current increase due to an increase in the content of the glass frit. Accordingly, it is possible to provide a conductive paste for a solar cell in which contact resistance is improved without a decrease in open-circuit voltage and an increase in leakage current, thereby improving the fill factor (FF) and efficiency of a solar cell manufactured by the conductive paste.

### EXAMPLES AND EXPERIMENTAL EXAMPLES

### Example 1

The paste composition for the lower portion printing layer of the electrode is as follows. For the silver powder, particles having D50=2.0 μm/ tap density=4.8 g/cm³ were used, and 89.0% by weight of the total paste composition was added. The glass frit was a Pb type having a Tg of 280° C., and 2.9% by weight of the glass frit and 0.1% by weight of WO₃ (0.1 μm) were added compared to the paste composition. As the resin, 0.5% by weight of a cellulose-based resin was added, and as an additive, 0.5% by weight of a thixotropic agent for imparting thixotropic properties was added, and 1.0% by weight of a dispersing agent was added. The remainder of the solvent was added at a ratio of 1.5 parts by weight of DBE and 3.5 parts by weight of buthyl carbitol acetate.

In the manufacture of the solar cell substrate, a 156 mm×156 mm single crystal silicon wafer was used. An emitter layer having a thickness of 100 to 500 nm having a sheet resistance of 90 Ω/sq was formed by doping phosphorus (P) through a diffusion process using POCl₃ at 900° C. in a tube furnace, and a silicon nitride layer as an anti-reflection film was formed on the emitter layer by using a PECVD method to have a thickness of 80 nm. The front electrode was screen-printed on the anti-reflection film. The lower portion printing layer of the front electrode was screen-printed with a Baccini printing machine using a 34 μm mask having a 15 μm emulsion film on a 360-16 mesh, and the paste composition for the upper portion printing layer was screen-printed on the lower portion printing layer in the same manner. For the rear electrode, screen printing was performed using a product from D Company. Thereafter, a drying process was performed using a BTU drying furnace at 300° C. for 30 seconds and then sintered in a sintering furnace at 900° C. for 60 seconds to manufacture a substrate for solar cells. The drying process was dried at 300° C. for 30 seconds using BTU drying furnace, and the sintering was sintered at 900° C. for 60 seconds using Despatch.

### Example 2

A process was performed in the same manner as in Example 1, except that 2.9% by weight of the same glass frit used in Example 1 was added, and 0.2% by weight of WO₃ (0.1 μm) was mixed.

### Example 3

A process was performed in the same manner as in Example 1, except that 2.9% by weight of the same glass frit used in Example 1 was added, and 0.3% by weight of WO₃ (0.1 μm) was mixed.

### Example 4

A process was performed in the same manner as in Example 1, except that 2.9% by weight of the same glass frit used in Example 1 was added, and 0.1% by weight of WO₃ (0.2 μm) was mixed

### Example 5

A process was performed in the same manner as in Example 1, except that 2.9% by weight of the same glass frit used in Example 1 was added, and 0.1% by weight of NiO₂ (0.1 μm) was mixed.

### Example 6

A process was performed in the same manner as in Example 1, except that 2.9% by weight of the same glass frit used in Example 1 was added, and 0.1% by weight of CuO (0.1 μm) was mixed.

### Example 7

A process was performed in the same manner as in Example 1, except that 2.9% by weight of the same glass frit used in Example 1 was added, and 0.1% by weight of Bi₂O₃ (0.1 μm) was mixed.

### Comparative Example 1

A process was performed in the same manner as in Example 1, except that 2.1% by weight of the same glass frit used in Example 1 was added.

### Comparative Example 2

A process was performed in the same manner as in Example 1, except that 2.3% by weight of the same glass frit used in Example 1 was added.

### Comparative Example 3

A process was performed in the same manner as in Example 1, except that 2.5% by weight of the same glass frit used in Example 1 was added.

### Comparative Example 4

A process was performed in the same manner as in Example 1, except that 2.7% by weight of the same glass frit used in Example 1 was added.

### Comparative Example 5

A process was performed in the same manner as in Example 1, except that 2.9% by weight of the same glass frit used in Example 1 was added.

### Comparative Example 6

A process was performed in the same manner as in Example 1, except that 3.1% by weight of the same glass frit used in Example 1 was added.

### Experimental Example

For the cells prepared according to Examples 1 to 7 and Comparative Examples 1 to 6, fill factor (FF) and resistance (Rser) were measured using a solar cell efficiency measuring equipment (CetisPV-Celltest 3, Halm Co., Ltd.). In addition, IV characteristics/EL characteristics were measured using HALM Electronics company's equipment. The leakage current value was measured by Suns-VOC, and the results are shown in Table 1 below.

TABLE 1

| | | WO₃ | WO₃ | | | | | | | Leak |
|---|---|---|---|---|---|---|---|---|---|---|
| | Glass | (0.1 | (0.2 | | | | FF | Voc | Rs | Current |
| Division | frit | μm) | μm) | NiO | CuO | Bi₂O₃ | [%] | [V] | [ohm] | [nA] |
| Example 1 | 2.9 | 0.1 | — | — | — | — | 81.35 | 0.6651 | 0.00073 | 3 |
| Example 2 | 2.9 | 0.2 | — | — | — | — | 81.17 | 0.6657 | 0.00085 | 2 |
| Example 3 | 2.9 | 0.3 | — | — | — | — | 80.98 | 0.6660 | 0.00095 | 2 |
| Example 4 | 2.9 | — | 0.1 | — | — | — | 81.15 | 0.6647 | 0.00085 | 5 |
| Example 5 | 2.9 | — | — | 0.1 | — | — | 80.82 | 0.6628 | 0.00125 | 7 |
| Example 6 | 2.9 | — | — | — | 0.1 | — | 80.91 | 0.6630 | 0.00108 | 6 |
| Example 7 | 2.9 | — | — | — | — | 0.1 | 80.93 | 0.6632 | 0.00117 | 6 |
| Comparative | 2.1 | — | — | — | — | — | 80.68 | 0.6655 | 0.00097 | 3 |
| Example 1 | | | | | | | | | | |
| Comparative | 2.3 | — | — | — | — | — | 80.82 | 0.6645 | 0.00091 | 5 |
| Example 2 | | | | | | | | | | |
| Comparative | 2.5 | — | — | — | — | — | 80.91 | 0.6638 | 0.00085 | 6 |
| Example 3 | | | | | | | | | | |
| Comparative | 2.7 | — | — | — | — | — | 81.04 | 0.6628 | 0.00079 | 8 |
| Example 4 | | | | | | | | | | |
| Comparative | 2.9 | — | — | — | — | — | 81.23 | 0.6615 | 0.00071 | 10 |
| Example 5 | | | | | | | | | | |
| Comparative | 3.1 | — | — | — | — | — | 81.07 | 0.6600 | 0.00067 | 15 |
| Example 6 | | | | | | | | | | |

Referring to Comparative Examples 1 to 6, as shown in Table 1, when the content of the glass frit is increased when the metal oxide is not included, the series resistance (Rs) decreases, and the fill factor (FF) increases, but at the same time it may be confirmed that the opening-voltage decreases and the leakage current increases.

In addition, referring to Comparative Example 5 and Examples 5 to 7, when NiO, CuO, and Bi₂O₃, which are metal oxides, are respectively added while maintaining a high content of glass frit (Examples 5 to 7), unlike the case where metal oxide is not included (Comparative Example 5), there is an effect of increasing the fill factor (FF) by preventing an increase in the leakage current value, but there is a problem in that the contact resistance characteristics are disadvantageous due to an increase in the series resistance Rs.

In addition, referring to Examples 1 and 2, when 0.1% to 0.2% by weight of the metal oxide WO₃ (0.1 μm) is added, it may be seen that there is an effect of increasing fill factor (FF) while preventing the increase of the leakage current value and the series resistance (Rs).

In addition, referring to Example 3, it can be confirmed that the increase in the leakage current value is prevented when WO₃ (0.1 μm) was added in an amount of 0.3% by weight or more, but in this case, the fill factor (FF) is reduced due to the failure of the series resistance (Rs).

Further, referring to Examples 1 and 4, when 0.1% by weight of WO₃ (0.2 μm) is added, as opposed to when 0.1% by weight of WO₃ (0.1 μm) is added, it may be confirmed that the leakage current increases, the serial resistance Rs increases, and the fill factor (FF) decrease. That is, it may be confirmed that the solar cell efficiency decreases as the particle size of the tungsten (W) metal oxide increases.

Therefore, there is a problem in that the leakage current value increases when the glass frit content is excessively added to increase the solar cell efficiency by increasing the fill factor (FF). It may be confirmed that adding a metal oxide in a range of 0.1% to 0.2% by weight of WO₃ (0.1 μm) in order to solve this problem tends to increase the fill factor (FF) while preventing an increase in the serial resistance (Rs) and the leakage current value.

Features, structures, effects, etc., exemplified in each of the above-described embodiments may be combined or modified for other embodiments by those of ordinary skilled in the art to which the embodiments belong. Accordingly, the contents related to such combinations and modifications should be interpreted as being included in the scope of the present disclosure.

1. A conductive paste for a solar cell electrode, the conductive paste comprising metal powder, glass frit, a metal oxide, an organic binder, and solvent, wherein the metal oxide comprises at least one metal oxide selected from the group consisting of tungsten (W), antimony (Sb), nickel (Ni), copper (Cu), magnesium (Mg), calcium (Ca), ruthenium (Ru), molybdenum (Mo), and bismuth (Bi).

2. The conductive paste of claim 1, wherein the content of the metal oxide is 0.01% to 0.5% by weight with respect to the total weight of the conductive paste.

3. The conductive paste of claim 1, wherein the average particle size of the metal oxide is in a range of 0.01 to 0.5 μm.

4. The conductive paste of claim 1, wherein the metal oxide comprises tungsten oxide (WO₃).

5. The conductive paste of claim 1, wherein the content of the glass frit is 0.5% to 5.0% by weight with respect to the total weight of the conductive paste.

6. A solar cell having a front electrode on an upper portion of a substrate and a rear electrode on a lower portion of the substrate, wherein the front electrode is manufactured by coating the conductive paste for a solar cell electrode of claim 1, drying and sintering.
